(19) United States
(12) Patent Application Publication
(10) Pub. No.: US 2026/0297748 A1
(43) Pub. Date: Oct. 1, 2026

(54) SYSTEM AND METHOD FOR FLOW-THROUGH ATOMIC LAYER DEPOSITION ON SEMICONDUCTOR PROCESSING TOOL COMPONENTS

(71) Applicant: Entegris, Inc., Billerica, MA (US)

(72) Inventor: Carlo Waldfried, Mystic, CT (US)

(21) Appl. No.: 19/631,478

(22) Filed: Mar. 27, 2026

Related U.S. Application Data
(60) Provisional application No. 63/780,150, filed on Mar. 28, 2025.

(51) Int. Cl. C23C 16/455; C23C 16/44

(52) U.S. Cl. CPC C23C 16/45561; C23C 16/4404; C23C 16/45553

(57) ABSTRACT

A system and method for flow-through atomic layer deposition on semiconductor processing tool components are provided. The system comprises a plurality of semiconductor processing tool components, each having a first end, a second end, an inner surface, and an outer surface. An inlet manifold is fluidly connected to the first end of each of the plurality of semiconductor processing tool components. An outlet manifold is fluidly connected to the second end of each of the plurality of semiconductor processing tool components. A heater element encloses each of the plurality of semiconductor processing tool components and controls a target temperature thereof. When a vaporized precursor is flowed through each of the semiconductor processing tool components from the first end to the second end under atomic layer deposition processing conditions, an ALD coating is formed on the inner surface of each of the plurality of semiconductor processing tool components.

### CROSS-REFERENCE TO RELATED APPLICATION

This application claims the benefit of and priority to U.S. Provisional Patent Application No. 63/780,150, filed on Mar. 28, 2025, the entire disclosure of which is hereby incorporated herein by reference.

### TECHNICAL FIELD

The present disclosure relates to vapor deposition systems and methods for applying coatings to inner surfaces of semiconductor processing tool components. More specifically, the present disclosure relates to systems comprising inlet and outlet manifolds for flow-through atomic layer deposition of protective coatings on inner surfaces of a plurality of semiconductor processing tool components in a single coating operation.

### BACKGROUND

Semiconductor device manufacturing involves the delivery of process fluids, including gases and liquids, to process tools through a network of fluid delivery components. These fluid delivery components can include, for example, gas lines, gas line manifolds, flexible lines, valves, filters, ampoules, bubblers, vaporizers, gas cylinders, reservoirs, pressure vessels, showerheads, and other components through which process fluids flow during semiconductor fabrication processes. Each of these components has an inner surface that contacts the process fluid during operation.

Process fluids used in semiconductor manufacturing can include precursor chemicals, co-reactant chemicals, etchant gases, cleaning agents, and carrier gases. Some process fluids are corrosive to the metallic materials from which fluid delivery components are typically fabricated, such as stainless steel. Exposure of the inner surfaces of fluid delivery components to corrosive process fluids can result in degradation of the component material over time. Metal ions or particles released from a degraded inner surface can enter the process fluid stream and be transported to the process tool, where they can contribute to defects in the semiconductor devices being manufactured.

Coatings can be applied to the inner surfaces of fluid delivery components to provide a barrier between the component material and the process fluid. Atomic layer deposition (ALD) is a vapor deposition technique in which a coating is formed by alternating, self-limiting exposures of complementary reactants to a surface. ALD coatings are conformal to the underlying surface topography and can be deposited with precise control of composition and thickness. Metal oxide coatings deposited by ALD, such as aluminum oxide and yttrium oxide, can provide corrosion resistance when applied to the inner surfaces of fluid delivery components.

### SUMMARY

The present disclosure relates to vapor deposition systems and methods for applying coatings to inner surfaces of semiconductor processing tool components.

Some embodiments relate to a system. In some embodiments, the system comprises a plurality of semiconductor processing tool components. In some embodiments, each of the plurality of semiconductor processing tool components has a first end, a second end, an inner surface, and an outer surface. In some embodiments, the system comprises an inlet manifold fluidly connected to the first end of each of the plurality of semiconductor processing tool components. In some embodiments, the system comprises an outlet manifold fluidly connected to the second end of each of the plurality of semiconductor processing tool components. In some embodiments, the system comprises a heater element enclosing each of the plurality of semiconductor processing tool components, wherein the heater element controls a target temperature of each of the plurality of semiconductor processing tool components. In some embodiments, when a vaporized precursor is flowed through each of the plurality of semiconductor processing tool components from the first end to the second end, under atomic layer deposition processing conditions, an ALD coating is deposited on the inner surface of each of the plurality of semiconductor processing tool components.

Some embodiments relate to a method for coating an inner surface of a semiconductor processing tool component. In some embodiments, the method comprises vaporizing a precursor to obtain a vaporized precursor. In some embodiments, the method comprises flowing the vaporized precursor through a system. In some embodiments, the system comprises a plurality of semiconductor processing tool components, each of the plurality of semiconductor processing tool components having a first end, a second end, an inner surface, and an outer surface. In some embodiments, the system comprises an inlet manifold fluidly connected to the first end of each of the plurality of semiconductor processing tool components. In some embodiments, the system comprises an outlet manifold fluidly connected to the second end of each of the plurality of semiconductor processing tool components. In some embodiments, the system comprises a heater element enclosing the plurality of semiconductor processing tool components, wherein the heater element controls a target temperature of each of the plurality of semiconductor processing tool components. In some embodiments, the vaporized precursor is flowed through the system under atomic layer deposition processing conditions. In some embodiments, the method comprises forming an ALD coating on the inner surface of each of the plurality of semiconductor processing tool components.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes it apparent to those skilled in the art how embodiments of the disclosure may be practiced.

FIG. 1 is schematic diagram of a conventional coating system.

FIG. 2 is a schematic diagram of a system, according to some embodiments.

FIG. 3 is schematic diagram of a flow-through coating system, according to some embodiments.

FIG. 4 is a flowchart of a method for flow-through coating semiconductor processing tool components, according to some embodiments.

FIG. 5 is photograph of the gas filter with its housing removed

FIG. 6 is graph showing the percent aluminum in a coating evaluated at different positions along the gas filter shown in FIG. 5.

FIG. 7 is a graph of a coating thickness on a witness coupon plotted against the TMA pulse.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the terms “about” and “approximately,” when used in connection with a numerical value, refer to a range of ±10% of the stated numerical value, unless otherwise indicated by context. For example, “about 100° C.” encompasses a range of 90° C. to 110° C.

When a numerical range is disclosed herein, any numerical value falling within the range is intended to be disclosed. The expressions “from X to Y,” “between X and Y,” “X to Y,” and similar expressions referring to a range of values, include X and Y and any value therebetween. Where a range of values is provided, each intervening value between the upper and lower limit of that range and any other stated or intervening value in that stated range is encompassed within the disclosure. The upper and lower limits of any stated range can independently be included or excluded in any narrower range within the stated range.

As used herein, the term “inner surface” of a semiconductor processing tool component refers to any surface of the semiconductor processing tool component that is exposed to a vaporized precursor when the vaporized precursor is flowed through the semiconductor processing tool component from the first end to the second end. For a semiconductor processing tool component having a tubular structure, such as a gas line, the inner surface can comprise the interior wall of the tube. For a semiconductor processing tool component having a porous or permeable structure, such as a filter or a filter membrane, the inner surface can comprise a plurality of surfaces, including surfaces within the porous or permeable structure through which the vaporized precursor passes. In some embodiments, the inner surface of a filter membrane includes surfaces on both sides of the membrane as well as surfaces within the membrane structure that are contacted by the vaporized precursor during the flow-through coating process. As used herein, the term “outer surface” of a semiconductor processing tool component refers to a surface of the semiconductor processing tool component that is not exposed to the vaporized precursor when the vaporized precursor is flowed through the semiconductor processing tool component from the first end to the second end. For example, for a gas line, the outer surface is the exterior wall of the tube. For a filter housed within a filter housing, the outer surface can comprise an exterior surface of the filter housing that is not contacted by the vaporized precursor.

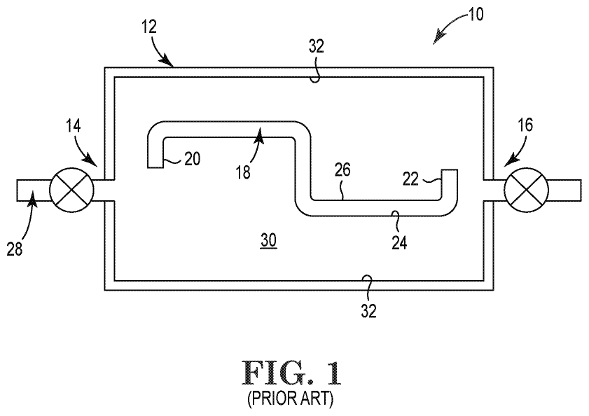

FIG. 1 is a schematic diagram of a conventional coating system 10 for coating a semiconductor processing tool component, according to some embodiments. As shown in FIG. 1, the conventional coating system 10 can comprise a chamber 12 having at least one inlet 14 and at least one outlet 16. A semiconductor processing tool component 18 is positioned within the chamber 12. The semiconductor processing tool component 18 has a first end 20, a second end 22, an inner surface 24, and an outer surface 26.

In operation of the conventional coating system 10, a vaporized precursor 28 is introduced through the inlet 14 of the chamber 12 and fills an interior volume 30 of the chamber 12. The vaporized precursor 28 flows from the inlet 14 through the interior volume 30 of the chamber 12 and exits through the outlet 16 of the chamber 12. Because the vaporized precursor 28 fills the entire interior volume 30 of the chamber 12, the vaporized precursor 28 contacts both the inner surface 24 and the outer surface 26 of the semiconductor processing tool component 18, as well as interior walls 32 of the chamber 12 itself. As a result, a coating is deposited on the inner surface 24, the outer surface 26, and the interior walls 32 of the chamber 12.

Conventional coating systems such as the conventional coating system 10 can present several limitations. Because the vaporized precursor 28 must fill the entire interior volume 30 of the chamber 12, a large quantity of vaporized precursor 28 may be consumed to coat even a single semiconductor processing tool component 18. The formation of a coating on the outer surface 26 of the semiconductor processing tool component 18 and on the interior walls 32 of the chamber 12 represents wasted precursor, as these surfaces typically do not require a coating for the intended application. For semiconductor processing tool components 18 having high aspect ratios, such as elongated gas lines or filters, extended process times may be required for the vaporized precursor 28 to diffuse through the interior volume 30 of the chamber 12 and uniformly reach the inner surface 24 along an entire length of the semiconductor processing tool component 18. In addition, the conventional coating system 10 is configured to coat a single semiconductor processing tool component 18 per coating cycle, which can limit manufacturing throughput

Systems and methods for flow-through coating of a plurality of semiconductor processing tool components are provided herein. The systems and methods disclosed herein can provide enhanced efficiency with respect to the formation of coatings on vapor-exposed surface portions of inner surfaces of semiconductor processing tool components. For example, vapor deposition coatings can be formed on the vapor-exposed surface portions of the inner surfaces of multiple semiconductor processing tool components. The flow-through coating systems and methods disclosed herein can require less precursor, relative to conventional systems, as a conventional deposition chamber does not need to be filled with the vaporized precursor to form vapor deposition coatings. The flow-through coating systems and methods disclosed herein can increase manufacturing production rates as long process times are not required, relative to conventional systems, for uniform deposition on high aspect ratio semiconductor processing tool components. The flow-through coating systems and methods disclosed herein can enhance the performance of semiconductor processing tool components by formation of continuous, uniform vapor deposition coatings on select surfaces of semiconductor processing tool components that can improve corrosion resistance, durability, among other things.

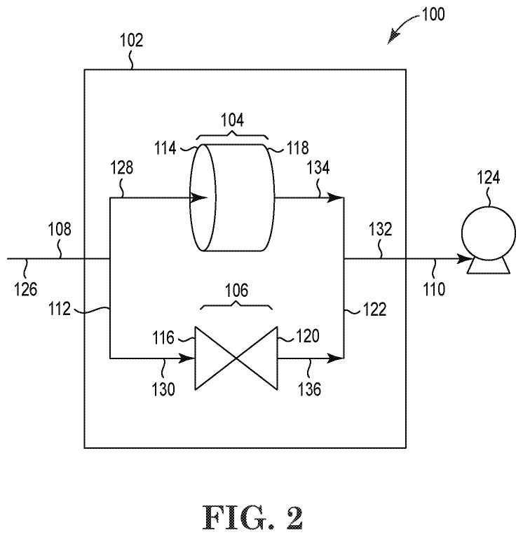

FIG. 2 is a schematic diagram of a system 100 for flow-through coating of a plurality of semiconductor processing tool components, according to some embodiments. As shown in FIG. 2, the system 100 comprises an inlet manifold 112, an outlet manifold 122, and a plurality of semiconductor processing tool components 104, 106. Each of the plurality of semiconductor processing tool components 104, 106 has a first end 114, 116, a second end 118, 120, an inner surface, and an outer surface. The inlet manifold 112 is fluidly connected to an inlet at the first end 114, 116 of each of the plurality of semiconductor processing tool components 104, 106, respectively. The outlet manifold 122 is fluidly connected to an outlet at the second end 118, 120 of each of the plurality of semiconductor processing tool components 104, 106, respectively. The inlet manifold 112 has an inlet 126 that is fluidly connected to a vaporized precursor source (not shown). The outlet manifold 122 has an outlet 132 that is fluidly connected to a vacuum source, such as a vacuum pump 124. In some embodiments, the system 100 further comprises a heater element 102 that encloses the plurality of semiconductor processing tool components 104, 106 and controls a target temperature thereof during a vapor deposition process. In operation, a vaporized precursor flows from the vaporized precursor source, through the inlet 126 of the inlet manifold 112, through the inner surface(s) of each of the plurality of semiconductor processing tool components 104, 106 from the first end 114, 116 to the second end 118, 120, through the outlet 132 of the outlet manifold 122, and to the vacuum pump 124.

The inlet manifold 112 has the inlet 126 and a plurality of outlets 128, 130. Each of the plurality of outlets 128, 130 is fluidly connected to the inlet at the first end 114, 116 of each of the plurality of semiconductor processing tool components 104, 106, respectively. The outlet manifold 122 has a plurality of inlets 134, 136 and the outlet 132. Each of the plurality of inlets 134, 136 is fluidly connected to the outlet at the second end 118, 120 of each of the plurality of semiconductor processing tool components 104, 106, respectively. In some embodiments, the inlet manifold 112 can comprise a symmetric branching configuration in which each branch from the inlet 126 to the plurality of outlets 128, 130 has a substantially equal flow path length and cross-sectional area to provide balanced vaporized precursor delivery to each of the plurality of semiconductor processing tool components 104, 106. Similarly, the outlet manifold 122 can comprise a symmetric branching configuration in which each branch from the plurality of inlets 134, 136 to the outlet 132 has a substantially equal flow path length and cross-sectional area to provide balanced exhaust flow from each of the plurality of semiconductor processing tool components 104, 106.

As shown in FIG. 2, the plurality of semiconductor processing tool components 104, 106 are arranged in the system 100 in parallel. In some embodiments, the plurality of semiconductor processing tool components 104, 106 can also be arranged in the system 100 in series (not shown). For example, in some embodiments, each of the plurality of semiconductor processing tool components 104, 106 is fluidly connected to each other via an adaptor (not shown) or other similar device, with at least the first end 114 of the first semiconductor processing tool component 104 fluidly connected to the inlet 126 of the inlet manifold 112, and the second end 120 of the last semiconductor processing tool component 106 fluidly connected to the outlet 132 of the outlet manifold 122.

The plurality of semiconductor processing tool components 104, 106 can comprise at least one of a first semiconductor processing tool component, a second semiconductor processing tool component, a third semiconductor processing tool component, a fourth semiconductor processing tool component, a fifth semiconductor processing tool component, a sixth semiconductor processing tool component, a seventh semiconductor processing tool component, an eighth semiconductor processing tool component, a ninth semiconductor processing tool component, a tenth semiconductor processing tool component, up to one-hundred or more semiconductor processing tool components. In some embodiments, the system 100 is configured to coat 2 to 100 semiconductor processing tool components per batch. It will be appreciated that although the system 100 is described herein with respect to a plurality of semiconductor processing tool components 104, 106, the system 100 can also be used with a single semiconductor processing tool component

In some embodiments, the plurality of semiconductor processing tool components 104, 106 are arranged by at least one of size, shape, length, width, or any combination thereof on the inlet manifold. The plurality of semiconductor processing tool components 104, 106 can be arranged in parallel, as shown, or in series. In cases, where a large number of semiconductor processing tool components are to be coated in a batch process, the components 104, 106 can be arranged both in parallel and in series.

The semiconductor processing tool component can be useful in semiconductor applications. For example, the semiconductor processing tool component can be part of a semiconductor device. In some embodiments, the semiconductor processing tool component has an inner surface and an outer surface. The semiconductor processing tool components can have varied sizes and shapes. The semiconductor processing tool components can have varied lengths and widths. The semiconductor processing tool component can be a 3D-printed article.

Non-limiting examples of the plurality of semiconductor processing tool components 104, 106 useful with the system 100 include at least one of a gas line, a gas line manifold, a flexible line, a valve, a check valve, a throttle valve, a filter, a filter membrane, a showerhead, a vacuum chamber, a vacuum chamber component, a vacuum tubing, a vacuum pipe, an ampoule, a bubbler, a precursor delivery vessel, a vaporizer, a sublimator, a gas cylinder, a reservoir, a pressure vessel, a mass flow controller, a pressure regulator, a fitting, a bellows, a chamber liner, a gas injector, a diffuser, a nozzle, a mixing manifold, an exhaust manifold, a foreline, a trap, or any combination thereof. In some embodiments, the semiconductor processing tool component is an in-line gas filter. In some embodiments, the semiconductor processing tool component is an ampoule. In some embodiments, the semiconductor processing tool component is a showerhead.

In some embodiments, the semiconductor processing tool component can have a structure having an aspect ratio. For example, in some embodiments, the aspect ratio of a semiconductor processing tool component can refer to a ratio of a depth to a width. In some embodiments, the aspect ratio of a semiconductor processing tool component can refer to a ratio of a width to a depth. In some embodiments, the aspect ratio of a semiconductor processing tool component can refer to a ratio of two of a length, a width, or a height. In some embodiments, the aspect ratio of a semiconductor processing tool component can refer to a ratio of a depth to a diameter. In some embodiments, the aspect ratio of a semiconductor processing tool component can refer to a ratio of a diameter to a depth. In some embodiments, the aspect ratio of a semiconductor processing tool component can refer to a ratio of at least two of the following: a width, a depth, a height, a diameter, and a circumference.

In some embodiments, the semiconductor processing tool component can have an aspect ratio of 2:1 to 1000:1, or any range or subrange therebetween. For example, the semiconductor processing tool component can have an aspect ratio of at least 2:1, at least 3:1, at least 4:1, at least 5:1, at least 6:1, at least 7:1, at least 8:1, at least 9:1, at least 10:1, at least 15:1, at least 20:1, at least 25:1, at least 30:1, at least 35:1, at least 40:1, at least 45:1, at least 50:1, at least 55:1, at least 60:1, at least 65:1, at least 70:1, at least 75:1, at least 80:1, at least 85:1, at least 90:1, at least 95:1, at least 100:1, at least 200:1, at least 300:1, at least 400:1, at least 500:1, at least 600:1, at least 700:1, at least 800:1, at least 900:1, to 1000:1, and/or any range or subrange therebetween.

The semiconductor processing tool component can minimize or eliminate corrosion of the semiconductor processing tool component, when, for example and without limitation, the semiconductor processing tool component is installed in corrosive environments at a facility.

In some embodiments, the semiconductor processing tool component can have a lifespan of 1 year to 5 years, or any range or subrange between 1 year and 5 years. For example, in some embodiments, the lifespan can have a range of 2 years to 5 years, 3 years to 5 years, 4 years to 5 years, 1 year to 4 years, 1 year to 3 years, 1 year to 2 years, 2 years to 4 years, or 2 years to 3 years. In some embodiments, the lifespan is measured by detecting an absence of pinholes in the ALD coating.

In some embodiments, the semiconductor processing tool component is capable of withstanding at least three (3) maintenance cycles in which the semiconductor processing tool component is exposed to 80% relative humidity for 24 hours at 25° C., wherein withstanding maintenance cycles is determined by detecting an absence of pinholes in the coating after the last maintenance cycle is performed. In some embodiments, when the semiconductor processing tool component is exposed to one or more cycles of 80% relative humidity at 25° C. for 24 hours, the semiconductor processing tool component does not exhibit, upon a visual inspection or other technique, pinholes formed in the coating.

The heater element 102 can comprise an enclosure configured for flow-through coating of semiconductor processing tool components. For example, the heater element 102 can comprise at least one of a heated enclosure, an oven, a heater box, a heater jacket, heat tape, or any combination thereof. In some embodiments, the heater element 102 comprises a heated enclosure. In some embodiments, the heater element 102 comprises an oven. In some embodiments, the heater element 102 is a vacuum-compatible enclosure. In some embodiments, the heater element 102 is a non-vacuum enclosure. In still other embodiments, the heater element 102 includes a heater jacket or heat tape that encloses each individual semiconductor processing tool component.

The heater element 102 can be configured to heat the plurality of semiconductor processing tool components to a target temperature. In some embodiments, a process temperature of each of the plurality of semiconductor processing tool components is controlled within 50° C. of the target temperature. The target temperature can comprise a temperature in a range of 20° C. to 500° C., or any range or subrange between 20° C. and 500° C. For example, in some embodiments, the target temperature is 20° C. to 500° C., 30° C. to 450° C., 50° C. to 400° C., 100° C. to 350° C., 150° C. to 300° C., or 200° C. to 250° C. In some embodiments, the target temperature is 30° C. to 500° C., 50° C. to 500° C., 100° C. to 500° C., 150° C. to 500° C., 200° C. to 500° C., 250° C. to 500° C., 300° C. to 500° C., 350° C. to 500° C., 400° C. to 500° C., or 450° C. to 500° C. In some embodiments, the target temperature is 20° C. to 450° C., 20° C. to 400° C., 20° C. to 350° C., 20° C. to 300° C., 20° C. to 250° C., 20° C. to 200° C., 20° C. to 150° C., 20° C. to 100° C., or 20° C. to 50° C.

The process temperature of each of the plurality of semiconductor processing tool components can be controlled within 1° C. to 50° C. of the target temperature, or any range or subrange of 1° C. to 50° C. For example, in some embodiments, the process temperature of each of the plurality of semiconductor processing tool components is controlled within 5° C. to 45° C., 10° C. to 40° C., 15° C. to 35° C., or 20° C. to 30° C. of the target temperature. In some embodiments, the process temperature of each of the plurality of semiconductor processing tool components is controlled within 1° C. to 45° C., 1° C. to 40° C., 1° C. to 35° C., 1° C. to 30° C., 1° C. to 25° C., 1° C. to 20° C., 1° C. to 15° C., 1° C. to 10° C., or 1° C. to 5° C. of the target temperature. In some embodiments, the process temperature of each of the plurality of semiconductor processing tool components is controlled within 5° C. to 50° C., 10° C. to 50° C., 15° C. to 50° C., 20° C. to 50° C., 25° C. to 50° C., 30° C. to 50° C., 35° C. to 50° C., 40° C. to 50° C., or 45° C. to 50° C. of the target temperature.

In some embodiments, the heater element 102 comprises a plurality of temperature zones, each of which is configured to control the process temperature of the semiconductor processing tool components within the respective zone to within a specified tolerance of the target temperature. For example, in some embodiments, the heater element 102 has a first temperature zone in which the process temperature of the semiconductor processing tool components is within 1° C. to 5° C. of the target temperature, a second temperature zone in which the process temperature is within 5° C. to 10° C. of the target temperature, a third temperature zone in which the process temperature is within 10° C. to 15° C. of the target temperature, and so forth.

The inlet manifold and the outlet manifold can each comprise a plurality of branches in parallel. The pressure, flow, or pump speed to each branch of the inlet manifold can be adjusted to allow for balanced vaporized precursor delivery into each of the plurality of semiconductor processing tool components. In some embodiments, the inlet manifold comprises a symmetric branching configuration as described herein. The pressure, flow, or pump speed to each branch of the outlet manifold can be similarly adjusted to allow for balanced vaporized precursor flow out of each of the plurality of semiconductor processing tool components. It will be appreciated that the systems disclosed herein, or any component thereof, including the inlet manifold and the outlet manifold, can include other components such as a coating performance monitor or a pressure measurement monitor. The coating performance monitor can comprise an optical monitoring system. The pressure measurement monitor can be a pressure gauge.

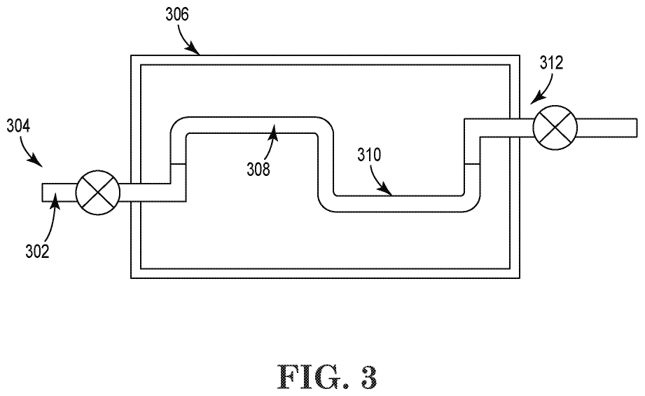

The systems described herein can be configured, such that, when a vaporized precursor is flowed through the semiconductor processing tool components, under atomic layer deposition conditions, the vaporized precursor is deposited on an inner surface of each of the plurality of semiconductor processing tool components, thereby forming an atomic layer deposition (ALD) coating, as shown in FIG. 3. In FIG. 3, the vaporized precursor 302 flows from the first end 304 of the semiconductor processing tool component 310 through an inner surface 308 of the semiconductor processing tool component 310 and through the second end 306 of the semiconductor processing tool component 310.

The semiconductor processing tool components disclosed herein can comprise uniform coatings over an entire length of the semiconductor processing tool component. The coating can comprise a vapor deposition coating. For example, in some embodiments, a vapor deposition coating refers to a coating that is deposited, via a vapor deposition process, on a surface of the semiconductor processing tool component. In some embodiments, for example, the coating is an ALD coating. It will be appreciated that the coating can be deposited on the semiconductor processing tool component via other types of vapor deposition processes, including, for example and without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

In some embodiments, the coating comprises a metal oxide of the formula: MO, where M is Zr, Ti, Cr, V, Ta, Mo, Ca, Mg, or Be. In some embodiments, the coating comprises a metal oxide of the formula M′O₂, where M′ is a metal having an oxidation state of 2+. In some embodiments, the coating comprises a metal oxide of the formula: Ln₂O₃, where Ln is a lanthanide (e.g., at least one of La, Sc, Y, or any combination thereof).

In some embodiments, the coating can comprise at least one of yttria, alumina, or any combination thereof. In some embodiments, the coating comprises yttria. In some embodiments, the coating comprises alumina. In still other embodiments, the coating can include both yttria and alumina forming a laminate or composite coating.

In still yet other embodiments, the coating comprises an aluminum oxide and a silicon oxide. In some embodiments, the aluminum oxide and the silicon oxide form a laminate coating.

In some embodiments, the vapor deposition coating is formed by performing a plurality of deposition cycles. In some embodiments, each deposition cycle comprises: (i) flowing at least a vaporized precursor from the inlet manifold, through the inner surface of each of the plurality of semiconductor processing tool components, and to the outlet manifold, such that the vaporized precursor adsorbs onto the inner surface of each of the plurality of semiconductor processing tool components; (ii) flowing a purge gas through the inner surface of each of the plurality of semiconductor processing tool components to remove un-adsorbed vaporized precursor and any byproducts; (iii) flowing at least a vaporized co-reactant precursor from the inlet manifold fluidly connected to each of the semiconductor processing tool components, through the inner surfaces of each of the plurality of semiconductor processing tool components, and to the outlet manifold, such that the vaporized co-reactant precursor reacts with the adsorbed precursor on the inner surface of each of the plurality of semiconductor processing tool components to form a monolayer or sub-monolayer of the coating; and (iv) flowing the purge gas through the inner surface of each of the plurality of semiconductor processing tool components to remove unreacted vaporized co-reactant precursor and any byproducts. In some embodiments, steps (i) through (iv) are repeated for a number of deposition cycles sufficient to achieve a target coating thickness. In some embodiments, the purge gas comprises an inert gas, such as, for example and without limitation, at least one of nitrogen, argon, helium, or any combination thereof.

In some embodiments, the vaporized precursor comprises a metal-containing precursor. For example, in some embodiments in which the coating comprises alumina, the vaporized precursor comprises trimethylaluminum and the vaporized co-reactant precursor comprises at least one of water, ozone, or oxygen plasma. In some embodiments in which the coating comprises yttria, the vaporized precursor comprises at least one of tris(methylcyclopentadienyl)yttrium, yttrium tris(2,2,6,6-tetramethyl-3,5-heptanedionate), or any combination thereof, and the vaporized co-reactant precursor comprises at least one of water, ozone, or oxygen plasma. In some embodiments, each deposition cycle deposits a layer having a thickness of 0.5 Å to 3 Å, or any range or subrange therebetween.

The coating can cover an inner surface of the semiconductor processing tool component. In some embodiments, the inner surface is not smooth. The inner surface can have at least one of a groove, an edge, a raised edge, a bump, or any combination thereof. The inner surface can have a groove. The inner surface can have an edge. The inner surface can have a raised edge. The inner surface can have a bump.

In some embodiments, the coating can cover 1% to 99% of an inner surface of the semiconductor processing tool component. For example, in some embodiments, the coating covers 5% to 95%, 10% to 90%, 15% to 85%, 20% to 80%, 25% to 75%, 30% to 70%, 35% to 65%, 40% to 60%, or 45% to 55% of an inner surface of the semiconductor processing tool component. In some embodiments, the coating covers 1% to 90%, 1% to 85%, 1% to 80%, 1% to 75%, 1% to 70%, 1% to 65%, 1% to 60%, 1% to 55%, 1% to 50%, 1% to 45%, 1% to 40%, 1% to 35%, 1% to 30%, 1% to 25%, 1% to 20%, 1% to 15%, 1% to 10%, 1% to 5% of an inner surface of the semiconductor processing tool component. In some embodiments, the coating covers 1% to 95%, 1% to 90%, 1% to 85%, 1% to 80%, 1% to 75%, 1% to 70%, 1% to 65%, 1% to 60%, 1% to 55%, 1% to 50%, 1% to 45%, 1% to 40%, 1% to 35%, 1% to 30%, 1% to 25%, 1% to 20%, 1% to 15%, 1% to 10%, or 1% to 5% of an inner surface of the semiconductor processing tool component. In some embodiments, the coating covers the inner surface of the semiconductor processing tool component in its entirety (i.e., 100%).

An average thickness of the coating can be 5 nm to 250 nm, or any range or subrange between 5 nm and 250 nm. For example, in some embodiments, the average thickness of the coating is 5 nm to 250 nm, 5 nm to 240 nm, 5 nm to 230 nm, 5 nm to 220 nm, 5 nm to 210 nm, 5 nm to 200 nm, 5 nm to 190 nm, 5 nm to 180 nm, 5 nm to 170 nm, 5 nm to 160 nm, 5 nm to 150 nm, 5 nm to 140 nm, 5 nm to 130 nm, 5 nm to 120 nm, 5 nm to 120 nm, 5 nm to 110 nm, 5 nm to 100 nm, 5 nm to 90 nm, 5 nm to 80 nm, 5 nm to 70 nm, 5 nm to 60 nm, 5 nm to 50 nm, 5 nm to 40 nm, 5 nm to 30 nm, 5 nm to 20 nm, 5 nm to 10 nm, 10 nm to 250 nm, 20 nm to 250 nm, 30 nm to 250 nm, 40 nm to 250 nm, 50 nm to 250 nm, 60 nm to 250 nm, 70 nm to 250 nm, 80 nm to 250 nm, 90 nm to 250 nm, 100 nm to 250, 110 nm to 250 nm, 120 nm to 250 nm, 130 nm to 250 nm, 140 nm to 250 nm, 150 nm to 250 nm, 160 nm to 250 nm, 170 nm to 250 nm, 180 nm to 250 nm, 190 nm to 250 nm, 200 nm to 250, 210 nm to 250 nm, 220 nm to 250 nm, 230 nm to 250 nm, or 240 nm to 250 nm.

In some embodiments, a thickness of the coating at any point along the inner surface is within 1% of an average thickness of the coating. In some embodiments, a thickness of the coating at any point along the inner surface is within 0.01% to 1% of an average thickness of the coating, or any range or subrange between 0.01% and 1%. For example, in some embodiments, a thickness of the coating at any point along the inner surface is within 0.1% to 0.9%, 0.2% to 0.8%, 0.3% to 0.7%, or 0.4% to 0.6% of an average thickness of the coating. In some embodiments, a thickness of the coating at any point along the inner surface is within 0.1% to 1%, 0.2% to 1%, 0.3% to 1%, 0.4% to 1%, 0.5% to 1%, 0.6% to 1%, 0.7% to 1%, 0.8% to 1%, 0.9% to 1% of an average thickness of the coating. In some embodiments, a thickness of the coating at any point along the inner surface is within 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, or 0.01% to 0.1% of an average thickness of the coating.

In some embodiments, a thickness of the coating at any point along the inner surface is within 10% of an average thickness of the coating. In some embodiments, a thickness of the coating at any point along the inner surface is within 0.1% to 10% of an average thickness of the coating, or any range or subrange between 0.1% and 10%. For example, in some embodiments, a thickness of the coating at any point along the inner surface is within 0.5% to 9%, 1% to 8%, 2% to 7%, 3% to 6%, or 4% to 5% of an average thickness of the coating. In some embodiments, a thickness of the coating at any point along the inner surface is within 0.5% to 10%, 1% to 10%, 2% to 10%, 3% to 10%, 4% to 10%, 5% to 10%, 6% to 10%, 7% to 10%, 8% to 10%, or 9% to 10% of an average thickness of the coating. In some embodiments, a thickness of the coating at any point along the inner surface is within 0.1% to 9%, 0.1% to 8%, 0.1% to 7%, 0.1% to 6%, 0.1% to 5%, 0.1% to 4%, 0.1% to 3%, 0.1% to 2%, 0.1% to 1%, 0.1% to 0.5% of an average thickness of the coating.

In some embodiments, the coating covers the inner surface of the semiconductor processing tool component. In some embodiments, the coating does not cover the outer surface of the semiconductor processing tool component.

The coating can have minimal defects based on a visual inspection using microscopy. For example, in some embodiments, the coating has less defects per square millimeter than a control coating. In some embodiments, the control coating is a coating that is different from the coating. In some embodiments, the control coating is a non-vapor deposition coating (e.g., a non-atomic layer deposition coating, etc.). In some embodiments, the control coating does not comprise alumina, nor yttria.

The coating can be pinhole free. In some embodiments, the coating can be pinhole free as determined by comparing a level of ions leached from a base material of the process fluid delivery line to purity of ultrapure water after soaking the line for a predetermined amount of time at 25° C. In some embodiments, the coating can be pinhole free as determined by the difference in the purity of a gaseous medium before and after being flowed through a semiconductor processing tool component comprising the coating being negligible. In some embodiments, the gaseous medium comprises ozone, a molybdenum vapor, or any other chemical vapor.

The vapor deposition conditions for the coating can comprise a deposition temperature. The deposition temperature can be a temperature less than the thermal decomposition temperature of the vaporized precursor. The deposition temperature can be sufficiently high to reduce or avoid condensation of the vaporized precursor. In some embodiments, the substrate can be heated to the deposition temperature.

The deposition temperature can be 100° C. to 500° C., or any range or subrange between 100° C. and 500° C. For example, in some embodiments, the deposition temperature can be 150° C. to 450° C., 200° C. to 400° C., or 250° C. to 350° C. In some embodiments, the deposition temperature can be 150° C. to 500° C., 200° C. to 500° C., 250° C. to 500° C., 300° C. to 500° C., 350° C. to 500° C., 400° C. to 500° C., or 450° C. to 500° C. In some embodiments, the deposition temperature can be 100° C. to 450° C., 100° C. to 400° C., 100° C. to 350° C., 100° C. to 300° C., 100° C. to 250° C., 100° C. to 200° C., or 100° C. to 150° C.

The vapor deposition conditions can comprise a deposition pressure. In some embodiments, the deposition pressure can comprise a vapor pressure of the vaporized precursor. In some embodiments, the deposition pressure can comprise a system pressure.

The deposition pressure can be a pressure of 0.001 Torr to 100 Torr, or any range or subrange between 0.001 Torr and 100 Torr. For example, in some embodiments, the deposition pressure can be a pressure of 0.1 Torr to 30 Torr, 0.1 Torr to 25 Torr, 0.1 Torr to 20 Torr, 0.1 Torr to 15 Torr, 0.1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure can be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure can be a pressure of 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 100 mTorr to 300 mTorr, 150 mTorr to 300 mTorr, 200 mTorr to 300 mTorr, or 150 mTorr to 250 mTorr, or 150 mTorr to 225 mTorr.

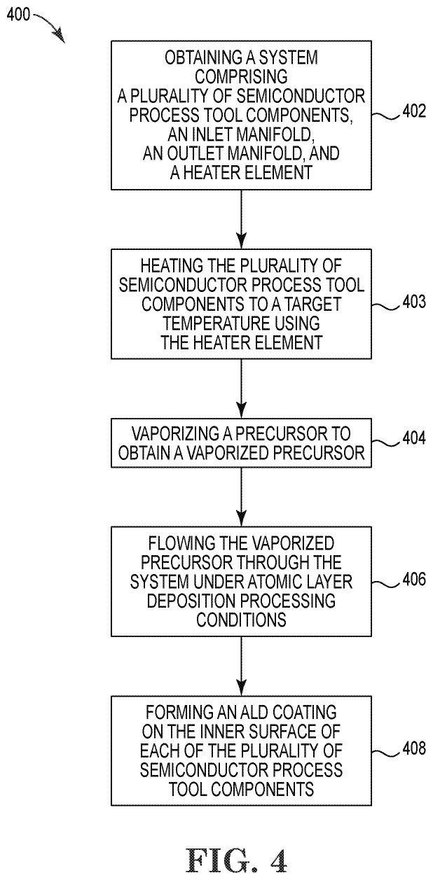

FIG. 4 is a flowchart of a method 400 for flow-through coating semiconductor processing tool components, according to some embodiments. As shown in FIG. 4, in some embodiments, the method 400 for flow-through coating semiconductor processing tool components comprises one or more of the following steps: obtaining 402 a system comprising a plurality of semiconductor processing tool components, an inlet manifold, an outlet manifold, and a heater element; heating 403 the plurality of semiconductor processing tool components to a target temperature using the heater element; vaporizing 404 at least a precursor to obtain a vaporized precursor; flowing 406, under atomic layer deposition processing conditions, the vaporized precursor through the system; and forming 408 an ALD coating on the inner surface of each of the plurality of semiconductor processing tool components.

At step 402, in some embodiments, the method 400 for flow-through coating semiconductor processing tool components comprises obtaining a system. The system can comprise any one or more of the systems disclosed herein. For example, in some embodiments, the system comprises at least one of a heater element, an inlet manifold, an outlet manifold, a plurality of semiconductor processing tool components, or any combination thereof. In some embodiments, each of the plurality of semiconductor processing tool components has a first end, a second end, an inner surface, and an outer surface. In some embodiments, the first end of each of the plurality of semiconductor processing tool components is fluidly connected to the inlet manifold. In some embodiments, the second end of each of the plurality of semiconductor processing tool components is fluidly connected to the outlet manifold. In some embodiments, the inlet manifold has an inlet fluidly connected to a vaporized precursor source. In some embodiments, the outlet manifold has an outlet fluidly connected to a vacuum source. In some embodiments, the heater element encloses the plurality of semiconductor processing tool components and controls a target temperature thereof. It will be appreciated that other variations and/or embodiments of the systems disclosed herein can be employed, without departing from the scope of this disclosure.

In some embodiments, the step of obtaining comprises installing each of the plurality of semiconductor processing tool components into the system. In some embodiments, the step of obtaining comprises connecting a first end of each of the semiconductor processing tool components to the inlet manifold. In some embodiments, the step of obtaining comprises connecting a second end of each of the semiconductor processing tool components to the outlet manifold. In some embodiments, the step of obtaining comprises connecting a first end of at least some of the semiconductor processing tool components to another semiconductor processing tool component via, for example, an adaptor or other similar device. In some embodiments, the step of obtaining comprises connecting a second end of at least some of the semiconductor processing tool components to another semiconductor processing tool component via, for example, an adaptor or other similar device.

In some embodiments, the method 400 comprises verifying vacuum conditions of the system. In some embodiments, the method 400 comprises obtaining adequate temperature conditions of the inlet manifold, the outlet manifold, or both. In some embodiments, the method 400 comprises obtaining adequate temperature conditions of the semiconductor processing tool components. In some embodiments, the method 400 comprises obtaining adequate temperature conditions of the precursor.

At step 403, in some embodiments, the method 400 for flow-through coating semiconductor processing tool components comprises heating the plurality of semiconductor processing tool components to a target temperature using the heater element. In some embodiments, the heater element heats each of the plurality of semiconductor processing tool components such that a process temperature of each of the plurality of semiconductor processing tool components is within a specified tolerance of the target temperature, as described herein. In some embodiments, the heater element is stabilized at the target temperature for a period of time prior to the vaporizing step 404 to allow the process temperature of each of the plurality of semiconductor processing tool components to equilibrate. In some embodiments, the period of time is at least 30 minutes, at least 45 minutes, or at least 60 minutes.

At step 404, in some embodiments, the method 400 for flow-through coating semiconductor processing tool components comprises vaporizing at least a precursor to obtain a vaporized precursor. In some embodiments, the vaporizing comprises heating at least a precursor sufficient to obtain the vaporized precursor. In some embodiments, the vaporizing comprises heating a container comprising the precursor. In some embodiments, the vaporizing comprises heating a conduit, such as a heated vapor supply line for delivering the precursor, the vaporized precursor, or any combination thereof to, for example, the inlet manifold. In some embodiments, the vaporizing comprises operating a vapor delivery system comprising the precursor. In some embodiments, the vaporizing comprises heating to a temperature sufficient to vaporize the precursor to obtain the vaporized precursor. In some embodiments, the vaporizing comprises heating to a temperature below a decomposition temperature of at least one of the precursor, the vaporized precursor, or any combination thereof.

In some embodiments, the method 400 comprises vaporizing at least a co-reactant precursor to obtain a vaporized co-reactant precursor. In some embodiments, the vaporizing comprises heating at least a co-reactant precursor sufficient to obtain a vaporized co-reactant precursor. In some embodiments, the vaporizing comprises heating a container comprising at least a co-reactant precursor. In some embodiments, the vaporizing comprises heating a conduit for delivering at least a co-reactant precursor, a vaporized co-reactant precursor, or any combination thereof to, for example, the inlet manifold. In some embodiments, the vaporizing comprises operating a chemical vapor deposition delivery system comprising the at least a co-reactant precursor and the precursor. In some embodiments, the vaporizing comprises heating to a temperature sufficient to vaporize at least a co-reactant precursor to obtain a vaporized co-reactant precursor. In some embodiments, the vaporizing comprises heating to a temperature below a decomposition temperature of at least one of a co-reactant precursor, a vaporized co-reactant precursor, or any combination thereof.

In some embodiments, the heating can occur at the deposition temperature described herein.

In some embodiments, the temperatures of the precursor and the co-reactant can be different from the temperatures of the semiconductor processing tool components, the inlet manifold, the outlet manifold, or any combination thereof.

The precursor, at least one co-reactant precursor, or any combination thereof can comprise at least one of an alkali metal, an alkaline earth metal, a transition metal, a post-transition metal, or any combination thereof.

The precursor, at least one co-reactant precursor, or any combination thereof can comprise a multi-metal oxide. In some embodiments, the multi-metal oxide comprises at least two metals in a form of an oxide. In some embodiments, the multi-metal oxide comprises a metal-oxy-fluoride. In some embodiments, the multi-metal oxide comprises a metal oxide and a metal-oxy-fluoride. In some embodiments, the multi-metal oxide comprises an amorphous multi-metal oxide.

The multi-metal oxide can comprise a first species and a second species. In some embodiments, the first species and the second species are different. In some embodiments, the multi-metal oxide comprises more than the first species and the second species. For example, in some embodiments, the multi-metal oxide further comprises a third species, a fourth species, a fifth species, a sixth species, a seventh species, an eighth species, a ninth species, a tenth species, or more than ten species, up to one-hundred species. It will be appreciated that, when more than two species are present in the multi-metal oxide, the species can be same or different and can comprise any one or more of the examples of the first species and/or second species disclosed herein, without departing from the scope of this disclosure.

The first species can comprise at least one of an alkali metal, an alkaline earth metal, a transition metal, a post-transition metal, or any combination thereof. In some embodiments, the first species comprises at least one of a lithium, a sodium, a potassium, a rubidium, a cesium, a francium, a beryllium, a magnesium, a calcium, a strontium, a barium, a radium, a scandium, a titanium, a vanadium, a chromium, a manganese, an iron, a cobalt, a nickel, a copper, a zinc, a yttrium, a zirconium, a niobium, a molybdenum, a technetium, a ruthenium, a rhodium, a palladium, a silver, a cadmium, a hafnium, a tantalum, a tungsten, a rhenium, an osmium, an iridium, a platinum, a gold, a mercury, an aluminum, a gallium, an indium, tin, a thallium, a lead, a bismuth, a polonium, or any combination thereof.

In some embodiments, the second species comprises at least one of an alkali metal, an alkaline earth metal, a transition metal, post-transition metal, or any combination thereof. In some embodiments, the second species comprises at least one of a lithium, a sodium, a potassium, a rubidium, a cesium, a francium, a beryllium, a magnesium, a calcium, a strontium, a barium, a radium, a scandium, a titanium, a vanadium, a chromium, a manganese, an iron, a cobalt, a nickel, a copper, a zinc, a yttrium, a zirconium, a niobium, a molybdenum, a technetium, a ruthenium, a rhodium, a palladium, a silver, a cadmium, a hafnium, a tantalum, a tungsten, a rhenium, an osmium, an iridium, a platinum, a gold, a mercury, an aluminum, a gallium, an indium, tin, a thallium, a lead, a bismuth, a polonium, or any combination thereof.

In some embodiments, the first species can comprise yttrium and the second species comprises aluminum. In some embodiments, the multi-metal oxide comprises at least one of an yttrium aluminum oxide (YAO), a fluorinated yttrium aluminum oxide, or any combination thereof. It will be appreciated that the multi-metal oxide can include oxides of any one or more of the first species and the second species. For example, in some embodiments, the multi-metal oxide comprises two or more of the following: an aluminum oxide, a silicon oxide, an yttrium oxide, a magnesium oxide, a calcium oxide, a zirconium oxide, a hafnium oxide, a boron oxide, or any combination thereof.

At step 406, in some embodiments, the method 400 for flow-through coating semiconductor processing tool components comprises flowing, under atomic layer deposition processing conditions, at least the vaporized precursor through the system from the inlet manifold, through the inner surface of each of the plurality of semiconductor processing tool components from the first end to the second end, and to the outlet manifold. The precursor can be exhausted from the system via the outlet of the outlet manifold.

In some embodiments, the flowing 406 comprises transporting the vaporized precursor with a carrier gas. In some embodiments, the flowing 406 comprises supplying the vaporized precursor to the inlet of the inlet manifold to flow through the system. In some embodiments, the flowing 406 comprises pumping the vaporized precursor to the inlet of the inlet manifold to flow through the system. In some embodiments, the flowing 406 comprises introducing the vaporized precursor to the inlet of the inlet manifold to flow through the system. In some embodiments, the flowing 406 comprises depositing the vaporized precursor to form the coating on the inner surface(s) of each of the plurality of semiconductor processing tool components in parallel. In some embodiments, the flowing 406 comprises conveying the vaporized precursor to the inlet of the inlet manifold to flow through the system. In some embodiments, the flowing 406 comprises drawing the vaporized precursor, for example, under vacuum, through the system from the inlet of the inlet manifold to the outlet of the outlet manifold. In some embodiments, the flowing 406 comprises flowing the vaporized precursor through the inner surface(s) of each of the plurality of semiconductor processing tool components from the first end to the second end.

The flowing of the vaporized precursor through the system, under atomic layer deposition processing conditions, can be for a deposition cycle time of 1 second to 5 minutes, or any range or subrange between 1 second to 5 minutes. In some embodiments, the vapor deposition process has a cycle time of 10 seconds to 4 minutes, 30 seconds to 3 minutes, or 1 minute to 2 minutes. In some embodiments, the vapor deposition process has a cycle time of 1 second to 4 minutes, 1 second to 3 minutes, 1 second to 2 minutes, 1 second to 1 minute, or 1 second to 30 seconds. In some embodiments, the vapor deposition process has a cycle time of 10 seconds to 5 minutes, 30 seconds to 5 minutes, 1 minute to 5 minutes, 2 minutes to 5 minutes, 3 minutes to 5 minutes, or 4 minutes to 5 minutes to obtain a predetermined coating thickness. The term “deposition cycle” refers to the steps by which a single layer of a coating is deposited on a semiconductor processing tool component.

In some embodiments, the method 400 comprises flowing simultaneously both the vaporized co-reactant precursor and the vaporized precursor through each of the semiconductor processing tool components from the first end to the second end. In some embodiments, the method 400 comprises flowing repeatedly in sequence both the vaporized co-reactant precursor and the vaporized precursor through each of the semiconductor processing tool components from the first end to the second end.

At least one of a flowrate of the carrier gas, a pressure of the carrier gas, or any combination thereof can be adjusted based on at least one of a size, a shape, a geometry, or any combination thereof of the semiconductor processing tool component being coated.

The carrier gas can have a flowrate of 10 standard cubic centimeters per minute (sccm) to 100 standard liters per minute (slm), or any range or subrange between 10 sccm and 100 slm. For example, in some embodiments, the carrier gas can have a flowrate of 10 sccm to 90 slm, 10 sccm to 80 slm, 10 sccm to 70 slm, 10 sccm to 60 slm, 10 sccm to 50 slm, 10 sccm to 40 slm, 10 sccm to 30 slm, 10 sccm to 20 slm, 10 sccm to 10 slm, 10 sccm to 9 slm, 10 sccm to 8 slm, 10 sccm to 7 slm, 10 sccm to 6 slm, 10 sccm to 5 slm, 10 sccm to 4 slm, 10 sccm to 3 slm, 10 sccm to 2 slm, 10 sccm to 1 slm, 10 sccm to 900 sccm, 10 sccm to 800 sccm, 10 sccm to 700 sccm, 10 sccm to 600 sccm, 10 sccm to 500 sccm, 10 sccm to 400 sccm, 10 sccm to 300 sccm, 10 sccm to 200 sccm, 10 sccm to 100 sccm, 10 sccm to 90 sccm, 10 sccm to 80 sccm, 10 sccm to 70 sccm, 10 sccm to 60 sccm, 10 sccm to 50 sccm, 10 sccm to 40 sccm, 10 sccm to 30 sccm, or 10 sccm to 20 sccm. In some embodiments, the carrier gas can have a flowrate of 20 sccm to 100 slm, 30 sccm to 100 slm, 40 sccm to 100 slm, 50 sccm to 100 slm, 60 sccm to 100 slm, 70 sccm to 100 slm, 80 sccm to 100 slm, 90 sccm to 100 slm, 100 sccm to 100 slm, 200 sccm to 100 slm, 300 sccm to 100 slm, 400 sccm to 100 slm, 500 sccm to 100 slm, 600 sccm to 100 slm, 700 sccm to 100 slm, 800 sccm to 100 slm, 900 sccm to 100 slm, 1 slm to 100 slm, 10 slm to 100 slm, 20 slm to 100 slm, 30 slm to 100 slm, 40 slm to 100 slm, 50 slm to 100 slm, 60 slm to 100 slm, 70 slm to 100 slm, 80 slm to 100 slm, or 90 slm to 100 slm.

At step 408, in some embodiments, the method 400 for flow-through coating semiconductor processing tool components comprises forming an ALD coating on the inner surface of each of the plurality of semiconductor processing tool components. In some embodiments, the ALD coating is as described herein.

In some embodiments, the method 400 comprises arranging the plurality of semiconductor processing tool components on the inlet manifold, such that, the vaporized precursor is deposited on the inner surface(s) of each of the plurality of semiconductor processing tool components in parallel. In some embodiments, the method 400 comprises arranging the plurality of semiconductor processing tool components on the inlet manifold, such that, the vaporized precursor is deposited on the inner surface(s) of each of the plurality of semiconductor processing tool components in series. In still other embodiments, the plurality of semiconductor processing tool components can be arranged both in parallel and in series. In some embodiments, the method 400 comprises arranging each of the plurality of semiconductor processing tool components on the inlet manifold by at least one of size, shape, length, width, or any combination thereof

### EXAMPLES

### Example 1

A 12″ gas filter was coated using the flow through coating method as described herein. The 12′ gas filter included a housing surrounding a stainless steel filter membrane, a flange, and a fitting. An ALD coating comprising aluminum oxide was deposited on the inner surfaces of each the gas filter. The vaporized precursor comprised trimethylaluminum (TMA) and the vaporized co-reactant precursor comprised water. The TMA and the water were flowed repeatedly in sequence through the symmetric branching inlet manifold, through the inner surface of each of the four gas filters, and through the outlet manifold, under atomic layer deposition processing conditions, to form the ALD coating.

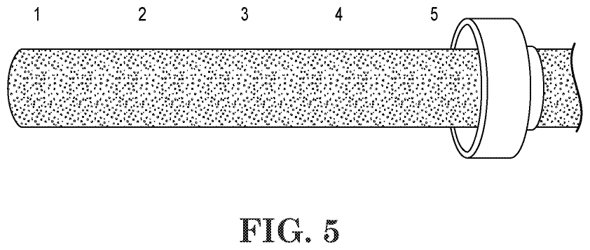

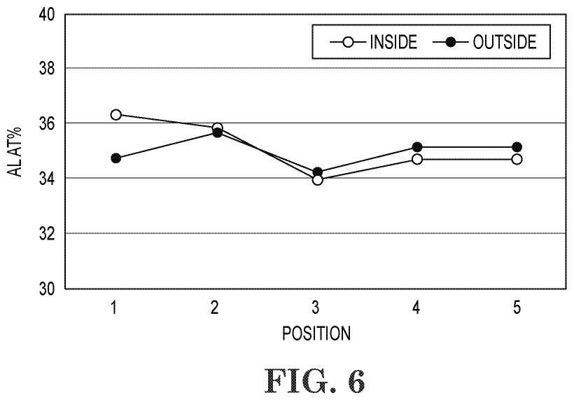

FIG. 5 is photograph of the gas filter with its housing removed such that what remains is the stainless steel cylindrical filter membrane, a flange, and a fitting. As shown in FIG. 5 the filter membrane was labeled at 5 positions along its length to measure the distribution of the ALD coating after the ALD coating was formed on the inner surface of the 12″ gas filter according to the methods as described herein. The uniformity of the ALD coating formed on the inner and outer surfaces filter membrane was determined by Energy Dispersive X-ray Analysis (EDX) at each of the five positions. A uniform signal was obtained across the membrane and along the length of the filter, from position 1 to position 5. FIG. 6 shows the percent of aluminum for both the inner and outer surface at each of the 5 positions of the filter membrane and demonstrating that the filter membrane was uniformly coated.

### Example 2

Four gas filters were coated in a batch process using the flow-through coating methods described herein. Each of the four gas filters comprised a stainless steel membrane having an inner surface and an outer surface surrounded by a housing. The four gas filters were arranged in parallel within a heater element. A first end of each gas filter was fluidly connected to an inlet manifold and a second end of each gas filter was fluidly connected to an outlet manifold. The inlet manifold was a symmetric branching manifold including a single inlet that branched into four outlets, with each branch having a substantially equal flow path length and cross-sectional area such that the vaporized precursor was delivered to each of the four gas filters in substantially equal amounts. A vacuum pump was fluidly connected downstream of the outlet manifold to draw the vaporized precursor through each of the four gas filters from the first end to the second end.

The heater element, which was a heater jacket, was used to heat the four gas filters to a target temperature. Prior to coating, the temperature of each of the four gas filters was measured after the heater element was heated to a target temperature and stabilized for approximately one hour. The measured temperature range across all four gas filters was approximately 1° C., confirming that the heater element provided a substantially uniform temperature-controlled environment to each of the four gas filters.

An ALD coating comprising aluminum oxide was deposited on the inner surface of each of the four gas filters. The vaporized precursor comprised trimethylaluminum (TMA) and the vaporized co-reactant precursor comprised water. The TMA and the water were flowed repeatedly in sequence through the symmetric branching inlet manifold, through the inner surface of each of the four gas filters, and through the outlet manifold, under atomic layer deposition processing conditions, to form the ALD coating. The coating recipe used was the same recipe previously developed for coating a single gas filter as described in Example 1, without modification.

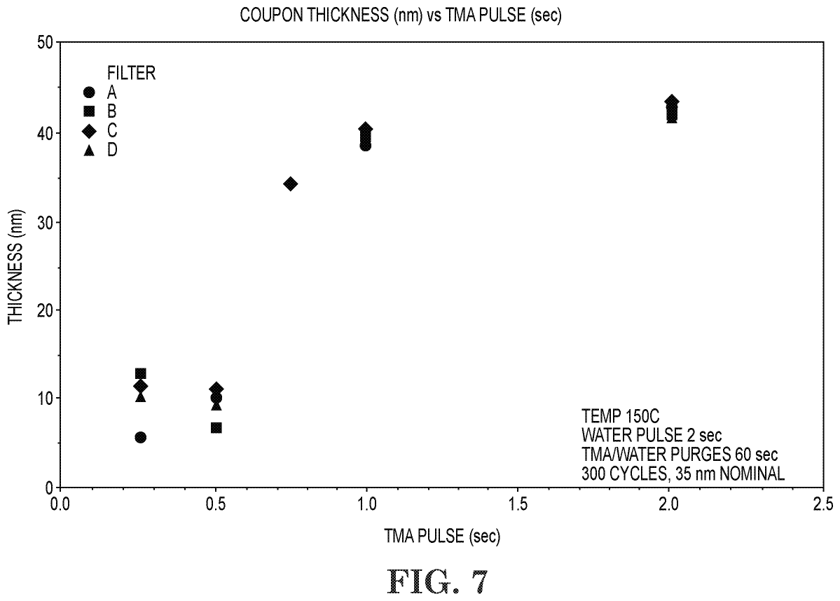

A witness coupon was positioned downstream of each of the four gas filters to monitor coating thickness. After the ALD coating was formed, the thickness of the ALD coating deposited on each of the four witness coupons was measured. As shown in FIG. 7, the measured witness coupon thicknesses were uniform across all four gas filters, confirming that the symmetric branching inlet manifold provided balanced precursor delivery to each of the four gas filters during the ALD coating process. The uniform witness coupon thicknesses demonstrated that the flow-through coating system was capable of coating a plurality of semiconductor processing tool components in parallel with a substantially uniform ALD coating using a single coating recipe.

In a separate coating run using the same four-filter configuration, the pulse time of the TMA was reduced. The reduced pulse time resulted in under-saturation of the ALD coating on the witness coupons, as indicated by a reduced coating thickness relative to the coating thickness obtained using the full pulse time. The under-saturation at shorter pulse times confirmed that the coating process was operating in a self-limiting ALD growth regime, in which the coating thickness per cycle was determined by the availability of adsorbed precursor on the inner surface of each gas filter rather than by an excess of precursor in the gas phase.

### Aspects

Various Aspects are described below. It is to be understood that any one or more of the features recited in the following Aspect(s) can be combined with any one or more other Aspect(s).

Aspect 1 is a system comprising a plurality of semiconductor processing tool components, each of the plurality of semiconductor processing tool components having a first end, a second end, an inner surface, and an outer surface; an inlet manifold fluidly connected to the first end of each of the plurality of semiconductor processing tool components; an outlet manifold fluidly connected to the second end of each of the plurality of semiconductor processing tool components; and a heater element enclosing each of the plurality of semiconductor processing tool components, wherein the heater element controls a target temperature of each of the plurality of semiconductor processing tool components, wherein when a vaporized precursor is flowed through each of the semiconductor processing tool components from the first end to the second end, an ALD coating is deposited on the inner surface of each of the plurality of semiconductor processing tool components.

Aspect 2 is the system of Aspect 1, wherein the inlet manifold has an inlet and a plurality of outlets, wherein the inlet of the inlet manifold is fluidly connected to a vaporized precursor source and the plurality of outlets of the inlet manifold is fluidly connected to the first end of each of the plurality of semiconductor processing tool components.

Aspect 3 is the system of any of Aspects 1-2, wherein the outlet manifold has a plurality of inlets and an outlet, wherein the plurality of inlets of the outlet manifold is fluidly connected to the second end of each of the plurality of semiconductor processing tool components.

Aspect 4 is the system of any of Aspects 1-3, further comprising a vacuum pump fluidly connected to the plurality of semiconductor processing tool components, wherein the vacuum pump is configured to apply a vacuum to draw the vaporized precursor into the inner surface of each of the plurality of semiconductor processing tool components.

Aspect 5 is the system of any of Aspects 1-4, wherein the plurality of semiconductor processing tool components comprises at least one of a gas line, a gas line manifold, a flexible line, a valve, a filter, a filter membrane, a showerhead, a vacuum chamber, a vacuum chamber component, a vacuum tubing, a vacuum pipe, an ampoule, a gas cylinder, a reservoir, a pressure vessel, or any combination thereof.

Aspect 6 is the system of any of Aspects 1-5, wherein the plurality of semiconductor processing tool components each comprises a filter.

Aspect 7 is the system of any of Aspects 1-5, wherein the plurality of semiconductor processing tool components each comprises an ampoule.

Aspect 8 is the system of any of Aspects 1-5, wherein the plurality of semiconductor processing tool components comprises a gas line.

Aspect 9 is the system of any of Aspects 1-8, wherein the plurality of semiconductor processing tool components are arranged in parallel, in series, or both.

Aspect 10 is the system of any of Aspects 1-9, wherein the heater element comprises at least one of a heated vacuum chamber, a heated non-vacuum chamber, a heated enclosure, an oven, a heater box, a heater jacket, heat tape, or any combination thereof.

Aspect 11 is the system of Aspect 10, wherein the heater element comprises an oven.

Aspect 12 is the system of Aspect 11, wherein the oven comprises two or more different heating zones.

Aspect 13 is a method for coating an inner surface of a semiconductor processing tool component comprising vaporizing a precursor to obtain a vaporized precursor; flowing the vaporized precursor through a system comprising a plurality of semiconductor processing tool components, each of the plurality of semiconductor processing tool components having a first end, a second end, an inner surface, and an outer surface, an inlet manifold fluidly connected to the first end of each of the plurality of semiconductor processing tool components, an outlet manifold fluidly connected to the second end of each of the plurality of semiconductor processing tool components, and a heater element enclosing the plurality of semiconductor processing tool components, wherein the heater element controls a target temperature of each of the plurality of semiconductor processing tool components, wherein the vaporized precursor is flowed through the system under atomic layer deposition processing conditions; and forming an ALD coating on the inner surface of each of the semiconductor processing tool components.

Aspect 14 is the method of Aspect 13, further comprising vaporizing at least a co-reactant precursor to obtain a vaporized co-reactant precursor, and flowing simultaneously both the vaporized co-reactant precursor and the vaporized precursor through each of the semiconductor processing tool components from the first end to the second end.

Aspect 15 is the method of Aspect 13, further comprising vaporizing at least a co-reactant precursor to obtain a vaporized co-reactant precursor, and flowing repeatedly in sequence both the vaporized co-reactant precursor and the vaporized precursor through each of the semiconductor processing tool components from the first end to the second end.

Aspect 16 is the method of Aspect 15, wherein the vaporized precursor is flowed through the semiconductor processing tool components in parallel.

Aspect 17 is the method of any of Aspects 15-16, further comprising controlling the process temperature of each of the plurality of semiconductor processing tool components within 50° C. of a target temperature of 20° C. to 500° C., to all surfaces of each of the plurality of semiconductor processing tool components.

Aspect 18 is the method of any of Aspects 15-17, further comprising controlling the process temperature of each of the plurality of semiconductor processing tool components within 25° C. of a target temperature of 20° C. to 500° C., to all surfaces of each of the plurality of semiconductor processing tool components.

Aspect 19 is the method of any of Aspects 15-18, further comprising controlling the process temperature of each of the plurality of semiconductor processing tool components within 5° C. of a target temperature of 20° C. to 500° C., to all surfaces of each of the plurality of semiconductor processing tool components.

Aspect 20 is the method of any of Aspects 13-19, wherein flowing the vaporized precursor through the system further comprises applying a vacuum to each of the plurality of semiconductor processing tool components.

Aspect 21 is the method of any of Aspects 13-20, wherein each of the semiconductor processing tool components comprises a filter.

Aspect 22 is the method of any of Aspects 13-20, wherein each of the semiconductor processing tool components comprises an ampoule.

Aspect 23 is the method of any of Aspects 13-20, wherein the heater element is an oven comprising two or more heating zones.

What is claimed is:

1. A system comprising:
a plurality of semiconductor processing tool components, each of the plurality of semiconductor processing tool components having a first end, a second end, an inner surface, and an outer surface,
an inlet manifold fluidly connected to the first end of each of the plurality of semiconductor processing tool components;
an outlet manifold fluidly connected to the second end of each of the plurality of semiconductor processing tool components; and
a heater element enclosing each of the plurality of semiconductor processing tool components, wherein the heater element controls a target temperature of each of the plurality of semiconductor processing tool components,
wherein when a vaporized precursor is flowed through each of the semiconductor processing tool components from the first end to the second end an ALD coating is deposited on the inner surface of each of the plurality of semiconductor processing tool components.

2. The system of claim 1, wherein the inlet manifold has an inlet and a plurality of outlets, wherein an inlet of the inlet manifold is fluidly connected to a vaporized precursor source and the plurality of outlets of the inlet manifold is fluidly connected to the first end of each of the plurality of semiconductor processing tool components.

3. The system of claim 1, wherein the outlet manifold has a plurality of inlets and an outlet, wherein the plurality of inlets of the outlet manifold is fluidly connected to the second end of each of the plurality of semiconductor processing tool components.

4. The system of claim 1, further comprises:
a vacuum pump fluidly connected to the plurality of semiconductor processing tool components, wherein the pump is configured to apply a vacuum to draw the vaporized precursor into the inner surface of each of the plurality of semiconductor processing tool components.

5. The system of claim 1, wherein the plurality of semiconductor processing tool components comprises at least one of a gas line, a gas line manifold, a flexible line, a valve, a filter, a filter membrane, a showerhead, a vacuum chamber, a vacuum chamber component, a vacuum tubing, a vacuum pipe, an ampoule, a gas cylinder, a reservoir, a pressure vessel, or any combination thereof.

6. The system of claim 1, wherein the plurality of semiconductor processing tool components each comprises a filter.

7. The system of claim 1, wherein the plurality of semiconductor processing tool components each comprises an ampoule.

8. The system of claim 1, wherein the plurality of semiconductor processing tool components comprises a gas line.

9. The system of claim 1, wherein the plurality of semiconductor processing tool components are arranged in parallel, in series, or both.

10. The system of claim 1, wherein the heater element comprises at least one of a heated vacuum chamber, a heated non-vacuum chamber, a heated enclosure, an oven, a heater box, a heater jacket, heat tape, or any combination thereof.

11. The system of claim 10, wherein the heater element comprises an oven.

12. The system of claim 11, wherein the oven comprises two or more different heating zones.

13. A method for coating an inner surface of a semiconductor processing tool component comprising:
vaporizing a precursor to obtain a vaporized precursor;
flowing the vaporized precursor through a system comprising
a plurality of semiconductor processing tool components, each of the plurality of semiconductor processing tool components having a first end, a second end, an inner surface, and an outer surface,
an inlet manifold fluidly connected to the first end of each of the plurality of semiconductor processing tool components,
an outlet manifold fluidly connected to the second end of each of the plurality of semiconductor processing tool components, and
a heater element enclosing the plurality of semiconductor processing tool components, wherein the heater element controls a target temperature of each of the plurality of semiconductor processing tool components,
wherein the vaporized precursor is flowed through the system under atomic layer deposition processing conditions; and
forming an ALD coating on the inner surface of each of the semiconductor processing tool components.

14. The method of claim 13, further comprising:
vaporizing at least a co-reactant precursor to obtain a vaporized co-reactant precursor; and
flowing simultaneously both the vaporized co-reactant precursor and the vaporized precursor through each of the semiconductor processing tool components from the first end to the second end.

15. The method of claim 13, further comprising:
vaporizing at least a co-reactant precursor to obtain a vaporized co-reactant precursor; and
flowing repeatedly in sequence both the vaporized co-reactant precursor and the vaporized precursor through each of the semiconductor processing tool components from the first end to the second end.

16. The method of claim 15, wherein the vaporized precursor is flowed through the semiconductor processing tool components in parallel.

17. The method of claim 15, further comprising controlling the process temperature of each of the plurality of semiconductor processing tool components within 50° C. of a target temperature of 20° C. to 500° C., to all surfaces of each of the plurality of semiconductor processing tool components.

18. The method of claim 15, further comprising controlling the process temperature of each of the plurality of semiconductor processing tool components within 25° C. of a target temperature of 20° C. to 500° C., to all surfaces of each of the plurality of semiconductor processing tool components.

19. The method of claim 15, further comprising controlling the process temperature of each of the plurality of semiconductor processing tool components within 5° C. of a target temperature of 20° C. to 500° C., to all surfaces of each of the plurality of semiconductor processing tool components.

20. The method of claim 15, wherein flowing the vaporized precursor through a system further comprises applying a vacuum to each of the plurality of semiconductor processing tool components.

21. The method of claim 15, wherein each of the semiconductor processing tool components comprises a filter.

22. The method of claim 15, wherein each of the semiconductor processing tool components comprises an ampoule.

23. The method of claim 15, wherein the heater element is an oven comprising two or more heating zones.
